(19) United States
(12) Patent Application Publication
(10) Pub. No.: US 2009/0152558 A1
(43) Pub. Date: Jun. 18, 2009

(54) Semiconductor device and method of manufacturing the same

(76) Inventor: Naoto Saito, Chiba-shi (JP)

Correspondence Address: BRUCE L. ADAMS, ESQ;ADAMS & WILKS, SUITE 1231, 17 BATTERY PLACE, NEW YORK, NY, 10004, US

(21) Appl. No.: 12/315,634

(22) Filed: Dec. 4, 2008

(30) Foreign Application Priority Data
Dec. 12, 2007 (JP) 2007-320971

(51) Int. Cl. H01L 29/78; H01L 21/336

(52) U.S. Cl. 257/66; 438/301; 257/E21.409; 257/E29.255

(57) ABSTRACT

Provided is a lateral semiconductor device with a trench structure for improving driving capability. A trench portion is formed in a well to give concave and convex portions in a gate width direction. A gate electrode is formed inside and above the trench portion with an insulating film therebetween. A source region is formed on one side of the gate electrode in a gate length direction, and a drain region is formed on the other side, both formed by impurity diffusion from polycrystalline silicon containing an impurity and filling the inside of the trench portion, deep enough to reach vicinity of the bottom of the gate electrode (vicinity of bottom of trench portion). By thus forming a deep source region and a deep drain region, current flow that would otherwise concentrate on a shallow part in the gate electrode becomes uniform throughout the trench portion and widening of an effective gate width owing to the concave and convex portions formed in the well lowers ON resistance, improving the driving capability.

### BACKGROUND OF THE INVENTION

1. Field of the Invention

The present invention relates to a semiconductor device constituted of a MOS transistor having trench structure, and to a method of manufacturing the semiconductor device.

2. Description of the Related Art

A MOS transistor is an electronic device occupying the core of electronic technology, and the reduction in size and enhancement of driving capability of MOS transistors are important challenges. One way to enhance the driving capability of a MOS transistor is increasing the gate width and thus lowering the ON resistance. Increase of the gate width, however, gives rise to a problem of larger area occupation by the MOS transistor. The following patent document 1 proposes a technology of increasing the gate width while preventing increase in the occupation area of a MOS transistor having lateral MOS structure (see, for example, JP 2006-49826 A).

The technology involves, as illustrated in a perspective view of FIG. 7(a), providing a trench portion 10 in a well 5, and forming a gate electrode 2 above and inside the trench portion 10 with an insulating film 7 interposed therebetween. In a surface layer of the well 5, a source region 61 is provided on one side of the gate electrode 2 and a drain region 62 is provided on the other side of the gate electrode 2. FIG. 7(b) is a sectional view taken along the line A-A of FIG. 7(a). FIG. 7(c) is a sectional view taken along the line B-B of FIG. 7(a). As illustrated in the B-B sectional view, with the gate electrode 2 formed inside the trench portion 10, the length of a zigzag trail measured along the insulating film 7 equals the gate width.

According to this technology, by employing a trench structure so that the gate portion has a convex portion and a concave portion, the effective gate width is made large with respect to the surface length of the gate electrode 2, and the ON resistance per unit area is thus lowered without withstanding voltage lowering of the MOS transistor.

A problem of the structure of FIG. 7(a) was found that the obtained driving capability is not as high as expected. In addition, the driving capability is varied depending on the gate length, and tends to drop when the gate length is short. It is presumed that this phenomenon is caused by non-uniform current flow in the channel generated between the source and the drain: most current flows along path A where the trench portion 10 is not formed; a little current flows along path B and path C as shown in FIG. 7D. Accordingly, the current tends to concentrate to the path A in the short gate length device, which is conceived to be a cause of the driving performance lowering in the short gate length device.

### SUMMARY OF THE INVENTION

An object of the present invention is to improve the driving capability of a semiconductor device having trench structure based on the above-mentioned presumption.

To attain this object, the present invention employs the following means:

1. A semiconductor device including: a semiconductor substrate; a first conductivity type well which is formed on the semiconductor substrate to have a concave portion whose depth varies along a gate width direction; a gate electrode formed above and inside the concave portion with an insulating film interposed therebetween; a second conductivity type source region which is formed on one side of the gate electrode to come to the vicinity of a bottom of the gate electrode; and a second conductivity type drain region which is formed on another side of the gate electrode to come to the vicinity of the bottom of the gate electrode, in which part of the second conductivity type source region and part of the second conductivity type drain region includes polycrystalline silicon regions.

2. The semiconductor device according to Item 1, in which bottoms of the source region and the drain region are disposed at the same depth with the bottom of the gate electrode, or at a point deeper than the bottom of the gate electrode.

3. The semiconductor device according to Item 1 or 2, in which at least one of the source region and the drain region includes a region adjacent to the gate electrode, in which a low impurity concentration is set.

According to the present invention, the driving capability of a semiconductor device can be improved by forming the source region and the drain region to come to the vicinity of the bottom of the gate electrode.

### BRIEF DESCRIPTION OF THE DRAWINGS

In the accompanying drawings:

FIG. 1 is a drawing illustrating a structure of a semiconductor device according to a first embodiment of the present invention;

FIG. 2 is a first set of step-by-step sectional views illustrating a method of manufacturing the semiconductor device according to the first embodiment of the present invention;

FIG. 3 is a drawing illustrating a structure of a semiconductor device according to a second embodiment of the present invention;

FIG. 4 is a first set of step-by-step sectional views illustrating a method of manufacturing the semiconductor device according to the second embodiment of the present invention;

FIG. 5 is a second set of step-by-step sectional views illustrating the method of manufacturing the semiconductor device according to the first embodiment of the present invention.

FIG. 6 is a second set of step-by-step sectional views illustrating the method of manufacturing the semiconductor device according to the second embodiment of the present invention; and

FIG. 7 is a drawing illustrating a conventional semiconductor device.

### DETAILED DESCRIPTION OF THE INVENTION

### (1) Outline of the Embodiment

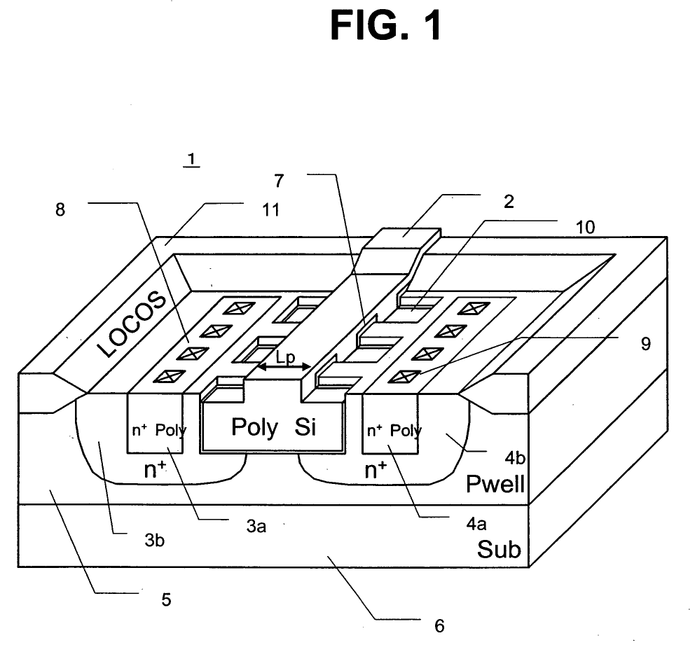

An embodiment mode is outlined first with reference to FIG. 1. A trench portion 10 is formed in a well 5 to give the well 5 concave and convex portions in a gate width direction. A gate electrode 2 is formed inside and above the trench portion 10 with an insulating film 7 interposed therebetween. A source region 3 is formed on one side of the gate electrode 2 in a gate length direction, and a drain region 4 is formed on the other side. The source region 3 is constituted of a polycrystalline silicon region 3a and a single-crystal silicon region 3b. The drain region 4 is constituted of a polycrystalline silicon region 4a and a single-crystal silicon region 4b. The source region 3 and the drain region 4 are both formed to a depth where the vicinity of the bottom of the gate electrode 2 (vicinity of bottom of trench portion 10) is located. By forming the source region 3 and the drain region 4 this deep, from the silicon surface to the trench bottoms, the current flow that would otherwise concentrate on a shallow part of the gate electrode 2 becomes uniform throughout each trench portion 10, and the concave and convex portions formed in the well 5 widen the effective gate width. The ON resistance of a semiconductor device 1 is thus lowered, which enhances the driving capability.

### (2) Details of Embodiments

FIG. 1 is a drawing illustrating the structure of a semiconductor device of this embodiment mode.

The semiconductor device 1 is a MOS transistor having a lateral MOS structure. The well 5 is formed on a semiconductor substrate 6, and the gate electrode 2, the source regions 3a and 3b, and the drain regions 4a and 4b are formed in the well 5. These elements are electrically isolated from other regions of the semiconductor substrate 6 by local oxidation of silicon (LOCOS) 11. The well 5 has a first conductivity type, whereas the source regions 3a and 3b and the drain regions 4a and 4b have a second conductivity type. When the first conductivity type is the conductivity type of a P-type semiconductor, the second conductivity type is the N type. When the first conductivity type is the conductivity type of an N-type semiconductor, the second conductivity type is the P type.

In the semiconductor device 1 of FIG. 1, the first conductivity type is the P type and the second conductivity type is the N type, which means that the well 5 is formed from a P-type semiconductor while the source regions 3a and 3b and the drain regions 4a and 4b are formed from an N-type semiconductor. The P type and the N type are discriminated from each other in FIG. 1 by denoting, for example, a well that has the P-type conductivity as “P-type well”. Although the semiconductor device 1 described in this embodiment mode has the above-mentioned structure, the same description can be applied to a case where the first conductivity type is the N type, the second conductivity type is the P type, and the well 5 is formed from an N-type semiconductor while the source regions 3a and 3b and the drain regions 4a and 4b are formed from a P-type semiconductor.

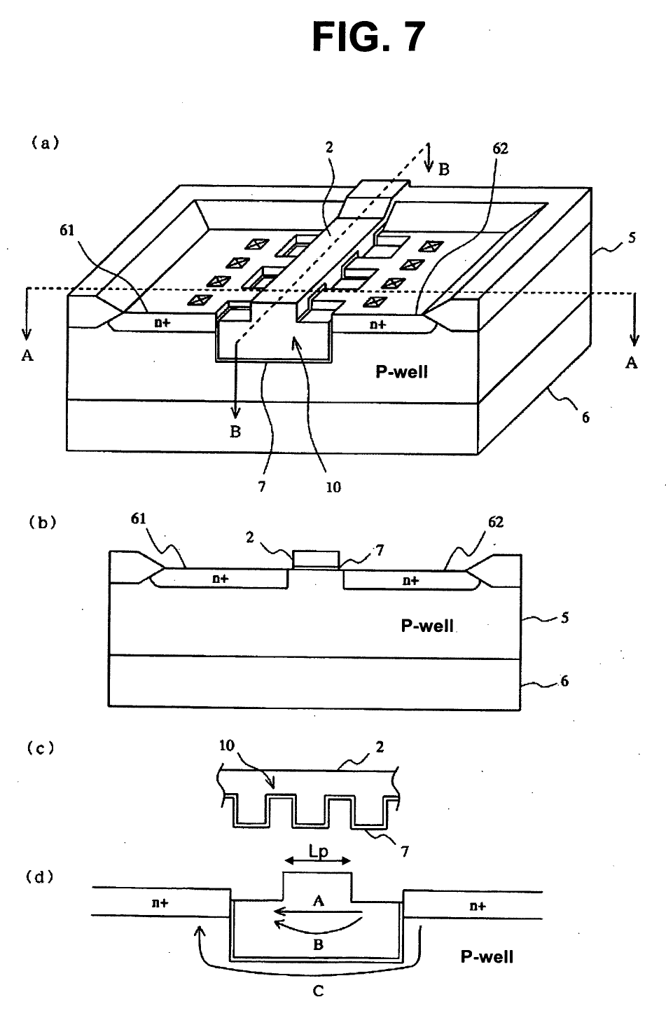

Multiple trench portions 10 which are concave portions are formed in the well 5 in the gate width direction, thereby varying the depth of the well 5 along the gate width direction. A direction to and from the source regions 3a and 3b and the drain regions 4a and 4b (Lp in the drawing) is the gate length direction. A direction parallel to the surface layer of the semiconductor device 1 and perpendicular to Lp is the gate width direction. The semiconductor device 1 which has multiple trench portions 10 in this embodiment mode may have a single trench portion 10 instead. Formed inside the trench portions 10 and on the top faces of the trench gate portions 10, namely, a face of the gate electrode 2 that faces the well 5, is the insulating film 7. The insulating film 7 is formed from SiO₂, for example. The gate electrode 2 is formed from polysilicon or the like inside and above the trench gate portions 10 with the insulating film 7 interposed therebetween. The trench gate portions 10 and the gate electrode 2 has the same structures as in the example of prior art illustrated in FIGS. 7(a) to 7(c).

The grooves of trench drain portions are filled with polycrystalline silicon that contains a large amount of impurity to form the polycrystalline silicon source region 3a and the polycrystalline silicon drain region 4a. The polycrystalline silicon source region 3a and the polycrystalline silicon drain region 4a are connected to the single-crystal silicon source region 3b and the single-crystal silicon drain region 4b, respectively. The source regions 3a and 3b are formed from an N-type semiconductor in one of side regions beside the gate electrode 2 in the gate length direction, and the drain regions 4a and 4b are formed from an N-type semiconductor in the other of the side regions. The depth of the source regions 3a and 3b and the drain regions 4a and 4b reaches the vicinity of the bottom of the gate electrode 2 (also referred to as vicinity of bottoms of trench portions 10). Multiple contacts 8 are formed in the source region 3 and multiple contacts 9 are formed in the drain region 4 to be junctioned with external circuits through metal wiring lines.

A symbol “n+” in the drawing indicates that the N-type concentration is high (i.e., heavily doped with N-type impurity). Low impurity concentration is indicated by “−” as in “n−”. An N-type semiconductor uses arsenic ions, phosphorus ions, or the like as an impurity. A P-type semiconductor uses boron ions or the like as an impurity.

Forming the source regions 3a and 3b and the drain regions 4a and 4b down to the vicinity of the bottom of the gate electrode 2 in this manner increases the current (transportation of carriers) that flows into the channel B and channel C illustrated in FIG. 7D, thereby widening the effective gate width. The driving capability of the semiconductor device 1 can thus be improved while preventing the semiconductor device 1 from occupying a larger area. In addition, the concentration of current on the channel A is mitigated even when the gate length Lp is short, and an excellent driving force is obtained.

The source regions 3a and 3b and the drain regions 4a and 4b in this embodiment mode are formed in the vicinity of the bottom of the gate electrode 2. The vicinity here is desirably a depth within ±20%, more desirably, within ±10%, from the bottom of the gate electrode 2 (bottoms of trench portions 10). In order to secure the effects that are obtained by forming a deep source region 3 and a deep drain region 4, it is desirable to make the bottoms of the source regions 3a and 3b and the drain regions 4a and 4b flush with, or lower than, the bottom of the gate electrode 2 (bottoms of trench portions 10).

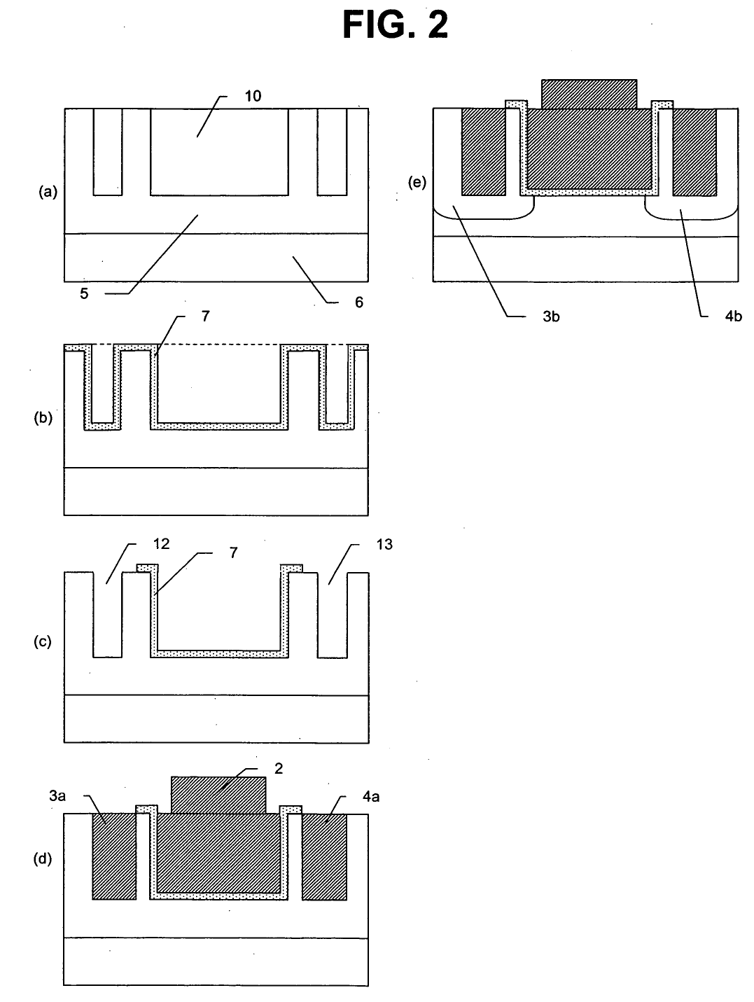

Next, a method of manufacturing the semiconductor device 1 is described with reference to FIG. 2, which is a first set of step-by-step sectional views illustrating a method of manufacturing the semiconductor device according to a first embodiment of the present invention.

To manufacture the semiconductor device 1, the LOCOS 11 (not shown in the drawings) and the well 5 are first formed on the semiconductor substrate 6. Next, as illustrated in FIG. 2(a), the trench gate portion 10, a trench drain portion 13, and a trench source portion 12 are formed in the well 5 by etching or the like. The insulating film 7 is formed inside the well 5, on the top face of the well 5, and on the inner wall of each of the trench portions (FIG. 2(b)). The insulating film is removed from the interiors of the trench source portion 12 and the drain trench portion 13 by etching (FIG. 2(c)). Polycrystalline silicon is deposited to fill the interiors of the trench source portion 12 and the drain trench portion 13 where the silicon surface is exposed, and the interior of the trench gate portion 10. After a high concentration of impurity is introduced into the polycrystalline silicon, the polycrystalline silicon is left only inside the trenches by etch-back. The impurity introduction method employed may be the pre-deposition method or ion implantation, or may be a doped polycrystalline silicon method in which polycrystalline silicon is deposited while an impurity is being introduced. The polycrystalline silicon source region 3a and the polycrystalline silicon drain region 4a are thus formed (FIG. 2(d)). Thereafter, the impurity is diffused from the polycrystalline silicon to the single-crystal silicon by heat treatment to form the single-crystal silicon source region 3b and the single-crystal silicon drain region 4b (FIG. 2(e)).

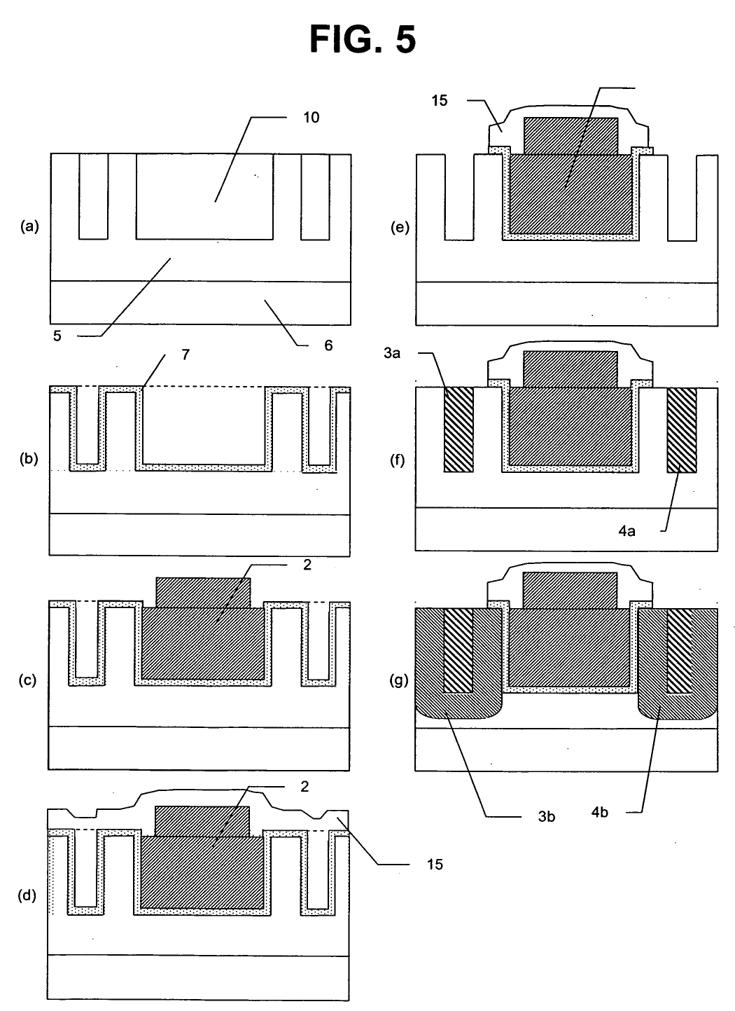

The process steps of FIG. 2 are arranged in this order: formation of the insulating film 7→etching the oxide film→filling with polycrystalline silicon→impurity diffusion. Alternatively, a changed order of the process steps may be employed: formation of the insulating film 7→filling the trench gate portion with polycrystalline silicon→etching the oxide film→filling the trench source portion and the trench drain portion with polycrystalline silicon→impurity diffusion. This takes more process steps but allows setting the impurity concentration of polycrystalline silicon for the gate and the drain separately, and hence the gate and the drain are each set to an optimum impurity concentration. Such process steps are next described with reference to FIG. 5.

FIG. 5 is a second set of step-by-step sectional views illustrating a method of manufacturing the semiconductor device according to the first embodiment of the present invention. The LOCOS 11 (not shown in the drawings) and the well 5 are first formed on the semiconductor substrate 6. Next, as illustrated in FIG. 5(a), the trench gate portion 10, the trench drain portion 13, and the trench source portion 12 are formed in the well 5 by etching or the like. Thereafter, the insulating film 7 is formed inside the well 5, on the top face of the well 5, and on the inner wall of each of the trench portions (FIG. 5(b)), polycrystalline silicon is deposited on the entire surface, and unnecessary polycrystalline silicon is removed so that only the trench gate portion 10 is filled with the polycrystalline silicon 2 (FIG. 5(c)). A CVD oxide film 15 is next deposited (FIG. 5(d)), the CVD oxide film 15 and the insulating film 7 are selectively removed from the source and drain regions (FIG. 5(e)), and the source and drain regions are filled with polycrystalline silicon to form the polycrystalline silicon source region 3a and the polycrystalline silicon 3b (FIG. 5(f)). Thereafter, the impurity is diffused from the polycrystalline silicon to the single-crystal silicon by heat treatment to form the single-crystal silicon source region 3b and the single-crystal silicon drain region 4b (FIG. 5(g)).

According to this embodiment mode described above, the following effects are obtained:

(1) The effective gate width is widened by employing a trench structure in which the gate electrode 2 is formed in the trench portion 10.

(2) By forming the deep source region 3 and the deep drain region 4 so that the bottoms of the source region 3 and the drain region 4 come to the vicinity of the bottom of the gate electrode 2, the electric current concentration on the shallow part of the trench structure is mitigated, which makes the trench structure effective in increasing the effective gate width.

(3) By forming the deep source region 3 and the deep drain region 4 so that the bottoms of the source regions 3a and 3b and the drain regions 4a and 4b come to the vicinity of the bottom of the gate electrode 2, the electric current concentration on the shallow part of the trench structure is mitigated even when the gate length is short.

(4) Since the effective gate width is widened, the ON resistance is lowered and the driving capability of the semiconductor device 1 is enhanced.

(5) A complementary metal oxide semiconductor (CMOS) structure having high driving capability can be created with one chip.

As has been described, in the semiconductor device 1, the well 5 is formed on the semiconductor substrate 6 to function as a first conductivity type well in which a concave portion (trench portion 10) varied in depth in the gate width direction is formed. The gate electrode 2 is formed above and inside the concave portion with the insulating film 7 interposed therebetween. The source region 3 functions as a second conductivity type source region formed on one side of the gate electrode 2 to come to the vicinity of the bottom of the gate electrode 2. The drain regions 4a and 4b function as a second conductivity type drain region formed on the other side of the gate electrode 2 to come to the vicinity of the bottom of the gate electrode 2. It is effective to form the source regions 3a and 3b and the drain regions 4a and 4b such that the bottoms of the source regions 3a and 3b and the drain regions 4a and 4b are flush with the bottom of the gate electrode 2, or at a point deeper than the bottom of the gate electrode 2.

The semiconductor device 1 is an N-channel transistor with the first conductivity type set as the P type and the second conductivity type set as the N type, but can be a P-channel transistor if the first conductivity type is the N type and the second conductivity type is the P type.

Described next is a semiconductor device in which a field relaxation region is provided in a drain region to improve the withstanding voltage of the semiconductor device.

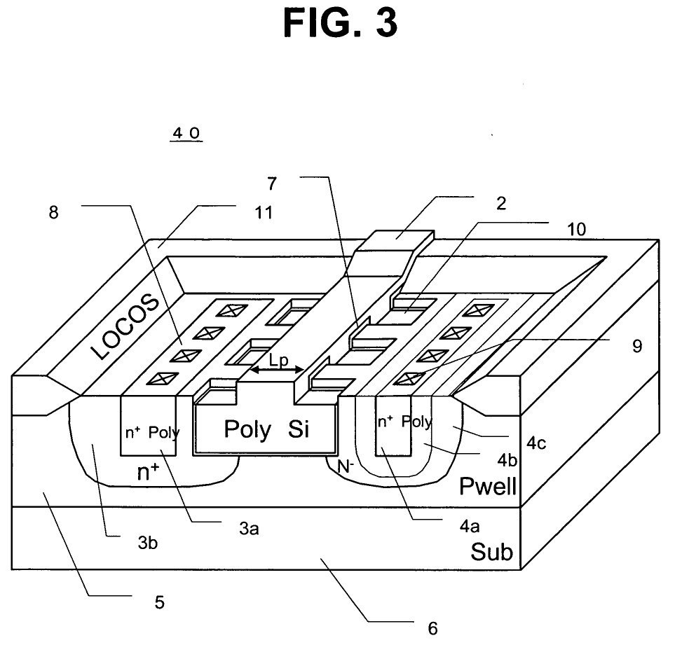

FIG. 3 is a drawing illustrating the structure of a semiconductor device according to a second embodiment of the present invention. The drain region structure of a semiconductor device 40 illustrated in FIG. 3 differs from that of the semiconductor device 1 illustrated in FIG. 1 in the following points:

The semiconductor device 40 of FIG. 3 has an n− region 4c, which is a lightly doped N-type region, in a region where the heavily doped single-crystal silicon drain region 4b faces the gate electrode 2. The n− region 4c comes to the vicinity of the bottom of the gate electrode 2. The n+ regions 4a and 4b, which are heavily doped N-type regions, have the same impurity concentration as that of the drain regions 4a and 4b in the semiconductor device 1 of FIG. 1. The contacts 9 are formed on the surface of the n+ region 4a. The source region structure in the semiconductor device 40 is the same as in the semiconductor device 1 of FIG. 1, but may include a lightly doped N type region similarly to the drain side. These differences in concentration are accomplished by, for example, forming an n− region within the trench drain portion through ion implantation, then filling the trench drain portion 12 with polycrystalline silicon, and performing the diffusion step. In short, the impurity concentration is set low in a part of the drain region of the semiconductor device 40 that is adjacent to the gate electrode 2.

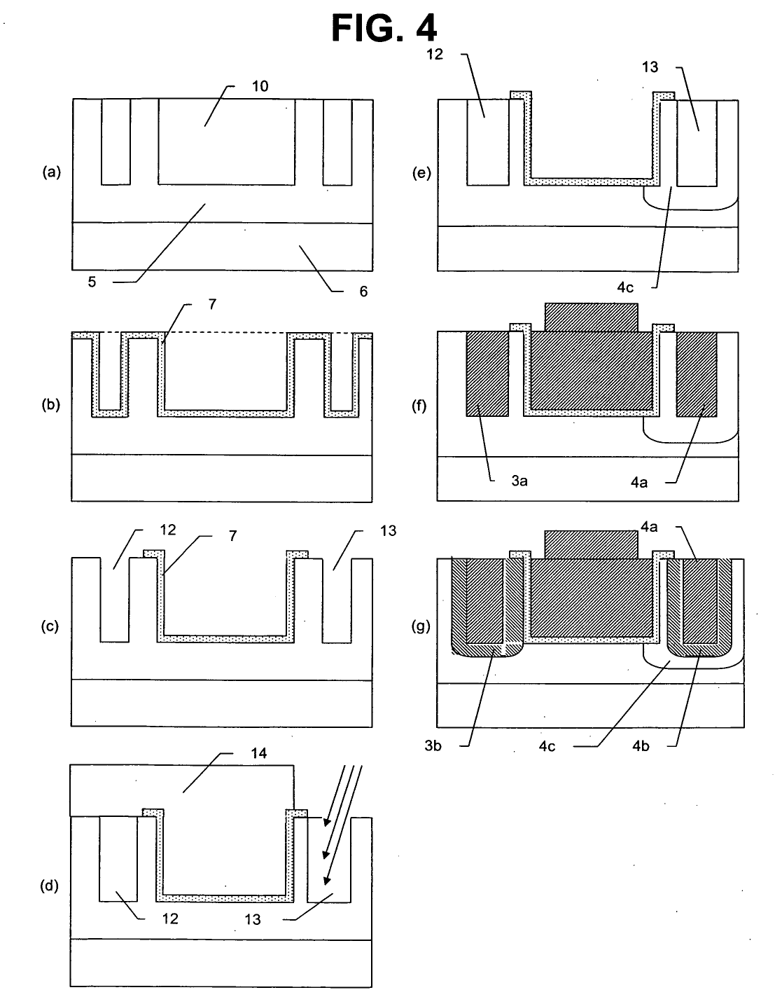

FIG. 4 is a first set of step-by-step sectional views illustrating a method of manufacturing the semiconductor device according to the second embodiment of the present invention.

To manufacture the semiconductor device 40, the LOCOS 11 (not shown in the drawings) and the well 5 are first formed on the semiconductor substrate 6. Next, as illustrated in FIG. 4(a), the trench gate portion 10, the trench drain portion 13, and the trench source portion 12 are formed in the well 5 by etching or the like. The insulating film 7 is formed inside the well 5, on the top face of the well 5, and on the inner wall of each of the trench portions (FIG. 4(b)). The oxide film is removed from the interiors of the trench source portion 12 and the drain trench portion 13 by etching (FIG. 4(c)). Subsequently, the trench gate portion 10 and the trench source portion 12 are masked with a resist 14 to dope the trench drain portion 13 with an N-type impurity by ion implantation (FIG. 4(d)). The impurity in the trench drain portion 13 is diffused by heat treatment to form the lightly doped N-type drain region 4c in a peripheral region of the trench drain portion 13 (FIG. 4(f)). Polycrystalline silicon is deposited to fill the interiors of the trench source portion 12 and the drain trench portion 13 where the silicon surface is exposed, and the interior of the trench gate portion 10. After a high concentration of impurity is introduced into the polycrystalline silicon, the polycrystalline silicon is left only inside the trenches by etch-back. The impurity introduction method employed may be the pre-deposition method or ion implantation, or may be a doped polycrystalline silicon method in which polycrystalline silicon is deposited while an impurity is being introduced. The polycrystalline silicon source region 3a and the polycrystalline silicon drain region 4a are thus formed (FIG. 4(d)). Thereafter, the impurity is diffused from the polycrystalline silicon to the single-crystal silicon by heat treatment to form the single-crystal silicon source region 3b and the single-crystal silicon drain region 4b (FIG. 4(e)).

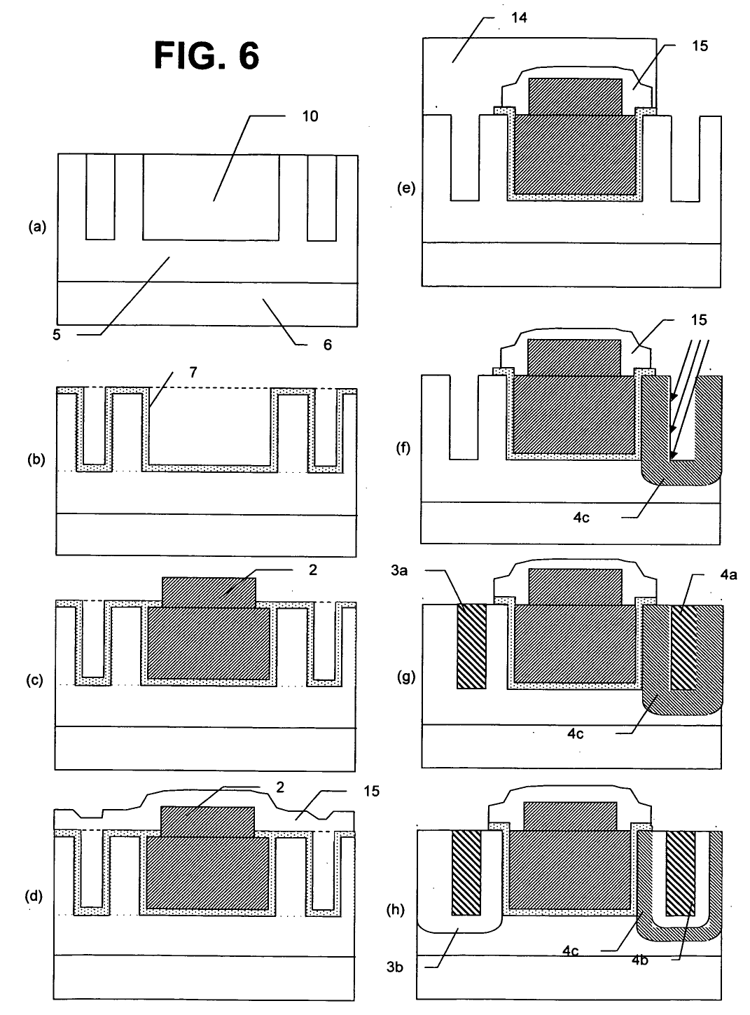

The process steps of FIG. 4 are arranged in this order: formation of the insulating film 7→etching the oxide film→filling with polycrystalline silicon→impurity diffusion. Alternatively, an order illustrated in FIG. 6 may be employed: formation of the insulating film 7→filling the trench gate portion with polycrystalline silicon→etching the oxide film→filling the trench source portion and the trench drain portion with polycrystalline silicon→impurity diffusion. This takes more process steps but allows setting the impurity concentration of polycrystalline silicon for the gate and the drain separately, and hence the gate and the drain are each set to an optimum impurity concentration. In this way, forming the lightly doped N-type region 4c between the gate electrode 2 and the n+ regions 4a and 4b relaxes the electric field in this region, and the withstanding voltage of the semiconductor device 40 is accordingly improved.

FIG. 6 is a second set of step-by-step sectional views illustrating a method of manufacturing the semiconductor device according to the second embodiment of the present invention. The LOCOS 11 (not shown in the drawings) and the well 5 are first formed on the semiconductor substrate 6. Next, as illustrated in FIG. 6(a), the trench gate portion 10, the trench drain portion 13, and the trench source portion 12 are formed in the well 5 by etching or the like. The insulating film 7 is formed inside the well 5, on the top face of the well 5, and on the inner wall of each of the trench portions (FIG. 6(b)). Polycrystalline silicon 2 is deposited to fill the trench gate portion 10 (FIG. 6(c)). A CVD oxide film 15 is next deposited (FIG. 6(d)), the CVD oxide film 15 and the insulating film 7 are selectively removed from the source and drain regions, and the trench source region 12 and the trench gate portion 10 are masked with the resist 14 (FIG. 6(e)). Next, the trench drain portion is doped with an N-type impurity by ion implantation. After the resist 14 is removed, the impurity is diffused by heat treatment to form the lightly doped N-type drain region 4c in a peripheral region of the trench drain portion 13 (FIG. 6(f)). The source region and the drain region are then filled with polycrystalline silicon to form the polycrystalline silicon source region 3a and the polycrystalline silicon 3b (FIG. 6(g)). Thereafter, the impurity is diffused from the polycrystalline silicon to the single-crystal silicon by heat treatment to form the single-crystal silicon source region 3b and the single-crystal silicon drain region 4b (FIG. 6(h)).

What is claimed is:

1. A semiconductor device comprising:
a semiconductor substrate;
a trench which is a concave portion formed in a vicinity of a first conductivity type surface of the semiconductor substrate and having a depth that varies along a gate width direction, the trench being filled with polycrystalline silicon that contains an impurity to form a source region and a drain region;
a polycrystalline silicon gate electrode including a part that fills an inside of the concave portion with an insulating film which is formed on a surface of the semiconductor substrate, being interposed therebetween, and a part that is placed on top faces of side walls of the concave portion;
a second conductivity type source region which is formed on one side of the gate electrode to come to the vicinity of a bottom of the gate electrode;
a second conductivity type drain region which is formed on another side of the gate electrode to come to the vicinity of the bottom of the gate electrode; and
polycrystalline silicon filling a part of the second conductivity type source region and part of the second conductivity type drain region in parallel with the gate electrode, and having contacts formed on a surface thereof.

2. A semiconductor device according to claim 1, wherein the source region and the drain region are formed by diffusing the impurity from the polycrystalline silicon.

3. A semiconductor device according to claim 1 or 2, wherein the polycrystalline silicon has a bottom flush with the bottom of the gate electrode, or at a point deeper than the bottom of the gate electrode.

4. A semiconductor device according to claim 1 or 2, wherein the source region and the drain region have bottoms flush with the bottom of the gate electrode, or at a point deeper than the bottom of the gate electrode.

5. A semiconductor device according to claim 1 or 2, wherein at least one of the source region and the drain region includes a region adjacent to the gate electrode, in which a low impurity concentration is set.

6. A method of manufacturing a semiconductor device, comprising the steps of:
forming a concave portion, a trench source portion, and a trench drain portion by etching in a vicinity of a first conductivity type surface of a semiconductor substrate, the concave portion being varied in depth along a gate width direction, the trench source portion and the trench drain portion being embedded with polycrystalline silicon that contains an impurity to form a source region and a drain region;
forming an insulating film on a surface of the semiconductor substrate including inner walls of the concave portion, the trench source portion, and the trench drain portion;
filling, after removing the insulating film from the inner walls of the trench source portion and the trench drain portion, insides of the concave portion, the trench source portion, and the trench drain portion with polycrystalline silicon that contains a high concentration of a second conductivity type impurity; and
diffusing the second conductivity type impurity from the polycrystalline silicon that fills the trench source portion and the trench drain portion to form the source region and the drain region.

7. A method of manufacturing a semiconductor device, comprising the steps of:
forming a concave portion, a trench source portion, and a trench drain portion by etching in a vicinity of a first conductivity type surface of a semiconductor substrate, the concave portion being varied in depth along a gate width direction, the trench source portion and the trench drain portion being embedded with polycrystalline silicon that contains an impurity to form a source region and a drain region;
forming an insulating film on a surface of the semiconductor substrate including inner walls of the concave portion, the trench source portion, and the trench drain portion;
filling an inside of the concave portion with polycrystalline silicon;
filling, after covering the polycrystalline silicon that fills the inside of the concave portion with an oxide film, and after removing the insulating film from the inner walls of the trench source portion and the trench drain portion, insides of the trench source portion and the trench drain portion with polycrystalline silicon that contains a high concentration of a second conductivity type impurity; and
diffusing the second conductivity type impurity from the polycrystalline silicon that fills the trench source portion and the trench drain portion to form the source region and the drain region.
